(19) United States
(12) Patent Application Publication
(10) Pub. No.: US 2021/0108833 A1
(43) Pub. Date: Apr. 15, 2021

(54) HEAT DISSIPATION DEVICE AND POWER GENERATOR

(71) Applicant: Panasonic Intellectual Property Management Co., Ltd., Osaka (JP)

(72) Inventors: Hisashi KANOU, Kumamoto (JP); Toshio MITSUYASU, Kumamoto (JP); Yutaka KUMANO, Hyogo (JP); Ichirou TAKAHARA, Osaka (JP)

(21) Appl. No.: 16/496,689

(22) PCT Filed: Mar. 22, 2018
(86) PCT No.: PCT/JP2018/011386

§ 371 Date: Sep. 23, 2019

(30) Foreign Application Priority Data
Mar. 24, 2017 (JP) 2017-060115

(51) Int. Cl. F25B 21/02

(52) U.S. Cl. CPC F25B 21/02; F28F 2215/08

(57) ABSTRACT

A heat dissipation device includes a base, a fin array, and an air flow channel. The fin array includes: a plurality of fins protruding in a first direction from the base and arranged side by side in a second direction that intersects with the first direction; and a reinforcing structure coupling two adjacent fins out of the plurality of fins. The air flow channel is surrounded, in the fin array, with the plurality of fins and the reinforcing structure and opens toward an end in the first direction.

### TECHNICAL FIELD

The present invention generally relates to a heat dissipation device and a power generator, and more particularly relates to a heat dissipation device with the ability to dissipate the heat generated from a heat source by air cooling and a power generator including such a heat dissipation device and having the ability to generate electricity by converting thermal energy into electric energy.

### BACKGROUND ART

A heat dissipation device with fins has been known and used extensively in the art as a device for dissipating the heat generated from a heat source. For example, Patent Literature 1 discloses a heat dissipation fin for dissipating the heat generated from a heat-generating part such as an LSI by air cooling.

Depending on the intended use, such a heat dissipation device may be exposed to vibrations, thus sometimes applying so heavy a load to the fin that damage could be done to the fin.

### CITATION LIST

### Patent Literature

Patent Literature 1: JP H07-254671 A

### SUMMARY OF INVENTION

It is therefore an object of the present invention to provide a heat dissipation device with the ability to reduce the damage to be done to itself when exposed to vibrations and exhibit good heat dissipation properties, and also provide a power generator including such a heat dissipation device.

A heat dissipation device according to an aspect of the present invention includes a base, a fin array, and an air flow channel. The fin array includes: a plurality of fins protruding in a first direction from the base and arranged side by side in a second direction that intersects with the first direction; and a reinforcing structure coupling two adjacent fins out of the plurality of fins. The air flow channel is surrounded, in the fin array, with the plurality of fins and the reinforcing structure and opens toward an end in the first direction.

A power generator according to another aspect of the present invention includes: a thermoelectric power generation module configured to convert thermal energy into electric energy; and the heat dissipation device attached to the thermoelectric power generation module.

### BRIEF DESCRIPTION OF DRAWINGS

FIG. 1A is a perspective view illustrating a heat dissipation device as a first example of an exemplary embodiment of the present invention;

FIG. 1B is a cross-sectional view of the heat dissipation device shown in FIG. 1A;

FIG. 2A is a perspective view illustrating a heat dissipation device as a second example of the exemplary embodiment of the present invention;

FIG. 2B is a cross-sectional view of the heat dissipation device shown in FIG. 2A;

FIG. 3A is a perspective view illustrating a heat dissipation device as a third example of the exemplary embodiment of the present invention;

FIG. 3B is a cross-sectional view of the heat dissipation device shown in FIG. 3A;

FIG. 4A is a perspective view illustrating a heat dissipation device as a fourth example of the exemplary embodiment of the present invention;

FIG. 4B is a cross-sectional view of the heat dissipation device shown in FIG. 4A;

FIG. 5A is a perspective view illustrating a heat dissipation device as a fifth example of the exemplary embodiment of the present invention;

FIG. 5B is a cross-sectional view of the heat dissipation device shown in FIG. 5A;

FIG. 6A is a perspective view illustrating a heat dissipation device as a first reference example;

FIG. 6B is a cross-sectional view of the heat dissipation device shown in FIG. 6A;

FIG. 7A is a perspective view illustrating a heat dissipation device as a second reference example;

FIG. 7B is a cross-sectional view of the heat dissipation device shown in FIG. 7A;

FIG. 8A is an exploded perspective view of a power generator according to an exemplary embodiment of the present invention; and

FIG. 8B is a front view of the power generator shown in FIG. 8A.

### DESCRIPTION OF EMBODIMENTS

### 1. Heat Dissipation Device

An overview of a heat dissipation device 1 according to an exemplary embodiment of the present invention will be described.

A heat dissipation device 1 according to this embodiment includes a base 2, a fin array 3, and an air flow channel 4. The fin array 3 includes a plurality of fins 5. The plurality of fins 5 protrude in a first direction D1 from the base 2 and are arranged side by side in a second direction D2 that intersects with the first direction D1. The fin array 3 further includes a reinforcing structure 6 coupling two adjacent fins 5 out of the plurality of fins 5. The air flow channel 4 is surrounded with the plurality of fins 5 and the reinforcing structure 6 in the fin array 3 and opens toward an end in the first direction D1.

The heat dissipation device 1 according to this embodiment achieves the advantage of reducing the damage to be done to itself when exposed to vibrations and exhibiting good heat dissipation properties.

As used herein, if some member is “coupled to” another member, then the term signifies that the two members are integrated together by welding, fusion bonding, adhesion, fitting, or any other technique or that the two members seamlessly form two integral parts of the same structure.

Also, if the air flow channel 4 is “surrounded with” the plurality of fins 5, then it means that at least one of the plurality of fins 5 is in contact with the air flow channel 4. Likewise, if the air flow channel 4 is “surrounded with” the reinforcing structure 6, then it means that at least some of the elements of the reinforcing structure 6 is in contact with the air flow channel 4. Examples of the elements of the reinforcing structure 6 include a reinforcing member 61, a second reinforcing member 62, a third reinforcing member 63, and a reinforcing plate 64 to be described later. In other words, if at least one element selected from the group consisting of the reinforcing member 61, the second reinforcing member 62, the third reinforcing member 63, and the reinforcing plate 64 is in contact with the air flow channel 4, then the air flow channel 4 is “surrounded with” the reinforcing structure 6.

When the heat dissipation device 1 according to this embodiment is used, the base 2 of the heat dissipation device 1, for example, may be arranged on a heat source. Then, the heat generated from the heat source is conducted to the fin array 3 via the base 2 and then radiated from the fin array 3.

The heat dissipation device 1 according to this embodiment allows the reinforcing structure 6 to increase the resonant frequency of the fin array 3 compared to a situation where no reinforcing structure 6 is provided. Thus, the reinforcing structure 6 is able to reduce the magnitude of displacement of the fin array 3 exposed to vibrations and thereby reduces the damage to be done to the fin array 3. In addition, although the fin array 3 includes the reinforcing structure 6, the air flow channel 4 still allows the air to flow smoothly through the fin array 3. This allows the heat dissipation device 1 to exhibit good heat dissipation properties.

These advantages of this embodiment will be described in further detail.

When a heat dissipation device is exposed to external vibrations, a dominant one of the vibrations produced in the heat dissipation device is a vibration, of which the frequency agrees with the resonant frequency of the fin array. The lower the resonant frequency is, the lower the frequency of the dominant vibration produced in the fin array becomes, thus increasing the degree of deformation of the fin array due to the vibration and also increasing the chances of damage being done to the fin array. In general, a fin has the shape of a flat plate with one end fixed and the other end free, and therefore, tends to have a low resonant frequency. This imparts a property vulnerable to vibrations to the fin array.

In contrast, according to this embodiment, the fin array 3 includes the reinforcing structure 6 that couples two adjacent fins 5 together, and therefore, may have a rigid structure. This increases the resonant frequency of the fin array 3. That is why even when the heat dissipation device 1 is exposed to vibrations, the reinforcing structure 6 increases the frequency of the dominant vibration produced in the fin array 3 and decreases the degree of deformation of the fin array 3, thus reducing the damage to be done to the fin array 3.

In addition, according to this embodiment, although the fin array 3 includes the reinforcing structure 6, which is usually capable of obstructing the air flow, the air flow channel 4 still facilitates the air flow through the fin array 3, thus allowing the heat dissipation device 1 to exhibit good heat dissipation properties.

In this embodiment, all of the spaces partitioned in the fin array 3 by constituent elements of the fin array 3 suitably either communicate with the air flow channel 4 or form at least part of the air flow channel 4. This allows the air flow channel 4 to improve the heat dissipation properties particularly significantly.

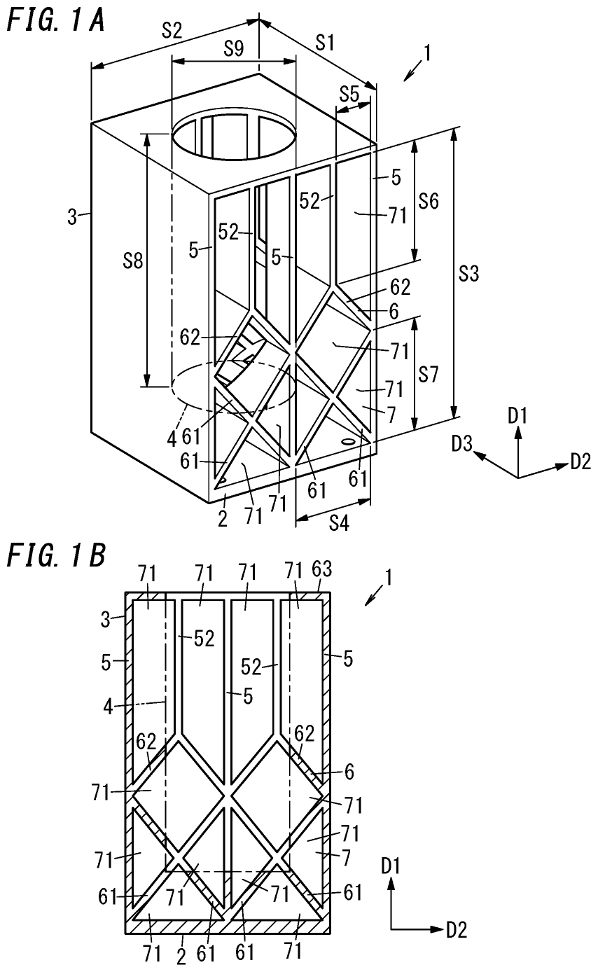

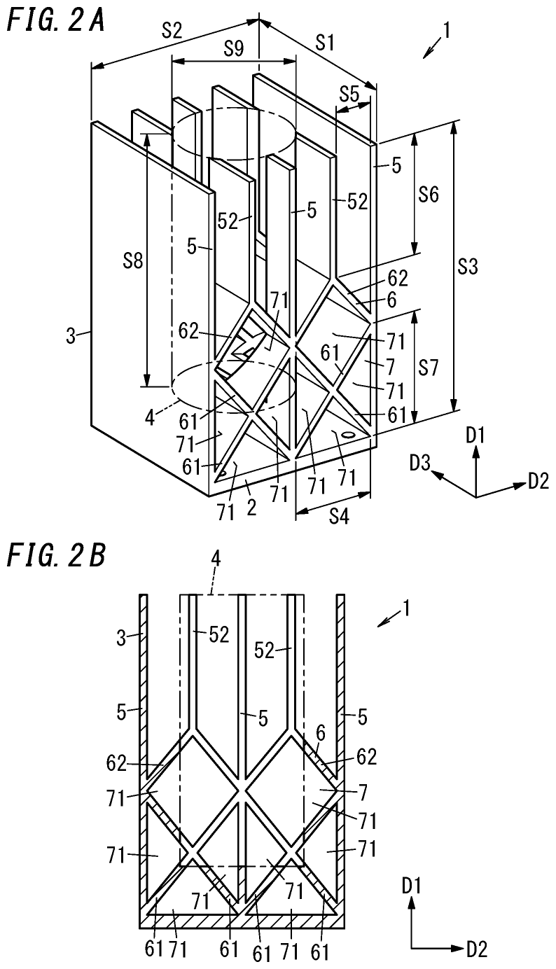

In the heat dissipation device 1 according to this embodiment, the reinforcing structure 6 may include a reinforcing member 61 bridged between the two adjacent fins 5 so as to be displaced in the first direction D1 and extend diagonally with respect to the second direction D2 (see FIGS. 1A and 2A). This allows the reinforcing member 61 to further increase the resonant frequency of the fin array 3.

In the heat dissipation device 1 according to this embodiment, when viewed in a third direction D3 intersecting with the first direction D1 and the second direction D2, the fin array 3 may keep the same shape anywhere in the third direction D3 except a region with the air flow channel 4 (see FIGS. 1A and 2A). This allows the fin array 3 to be formed by extrusion.

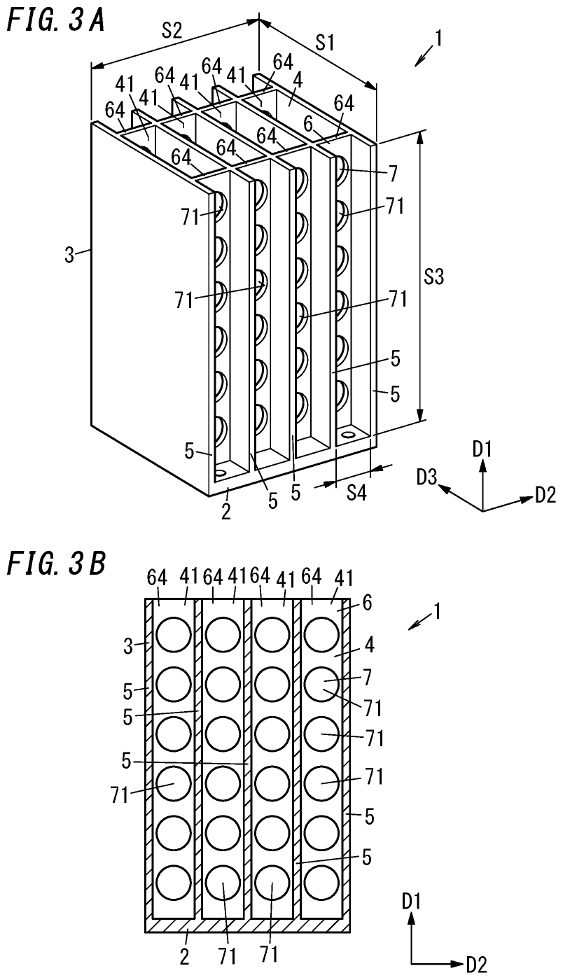

In the heat dissipation device 1 according to this embodiment, the reinforcing structure 6 may include two reinforcing plates 64 bridged between the two adjacent fins 5 and facing each other in a third direction D3 that intersects with the first direction D1 and the second direction D2. The air flow channel 4 may include a flow channel 41 surrounded with the two fins 5 and the two reinforcing plates 64 (see FIGS. 3A, 4A, and 5A). This allows the reinforcing plates 64 to further increase the resonant frequency of the fin array 3, and also allows the flow channel 41 to improve the heat dissipation properties of the heat dissipation device 1.

In the heat dissipation device 1 according to this embodiment, the air flow channel 4 may include a plurality of flow channels 41 (see FIGS. 3A, 4A, and 5A). This allows the plurality of flow channels 41 to improve the heat dissipation properties of the heat 6 dissipation device 1.

When the air flow channel 4 includes a plurality of flow channels 41, the reinforcing structure 6 may include two reinforcing plates 64 bridged between the two adjacent fins 5 and facing each other in the third direction D3 that intersects with the first direction D1 and the second direction D2. The plurality of flow channels 41 may include a flow channel 41 surrounded with the two fins 5 and the two reinforcing plates 64.

The heat dissipation device 1 according to this embodiment may further include an air inlet port 7 that allows the air flow channel 4 to communicate with outside of the fin array 3 in a direction intersecting with the first direction D1 (see FIGS. 1A, 2A, 3A, 4A, and 5A). This causes the air inlet port 7 to produce a stack effect in the air flow channel 4, thus further improving the heat dissipation properties of the heat dissipation device 1.

In the heat dissipation device 1 according to this embodiment, the reinforcing structure 6 may form the air inlet port 7 (see FIGS. 1A and 2A). This allows the reinforcing structure 6 to have not only the capability of lowering the resonant frequency of the fin array 3 but also the capability of improving the heat dissipation properties of the heat dissipation device 1.

In the heat dissipation device 1 according to this embodiment, the air inlet port 7 may be cut through the reinforcing structure 6 (see FIGS. 3A, 4A, and 5A). This allows the reinforcing structure 6 to have not only the capability of lowering the resonant frequency of the fin array 3 but also the capability of improving the heat dissipation properties of the heat dissipation device 1.

In the heat dissipation device 1 according to this embodiment, the fin array 3 may further include a second fin 52 protruding in the first direction D1 from the reinforcing structure 6 and having a shorter dimension as measured in the first direction D1 than the plurality of fins 5 (see FIGS. 1A and 2A). This allows the reinforcing structure 6 to support the second fin 52 and also allows the second fin 52 to improve the heat dissipation properties of the heat dissipation device 1.

Now, first to fifth examples will be described as more specific examples of the heat dissipation device 1 according to this embodiment. When the second through fifth examples are described, any constituent element of the second, third, fourth, or fifth example, having substantially the same function as a counterpart of the heat dissipation device 1 according to the first example, will not be described all over again to avoid redundancies. Note that the following specific examples of the heat dissipation device 1 according to this embodiment should not be construed as limiting, and that some constituent elements thereof may be readily replaced, omitted, or combined with additional elements as needed in various manners.

### 1-1. First Example

A first example of the heat dissipation device 1 will be described with reference to FIGS. 1A and 1B. In FIGS. 1A and 1B, the first, second, and third directions D1, D2, and D3 according to the first example are also shown. The second direction D2 intersects with the first direction D1, and the third direction D3 intersects with the first and second directions D1 and D2. As can be seen, these directions only need to intersect with each other. In the first example, the second direction D2 is perpendicular to the first direction D1, and the third direction D3 is perpendicular to the first and second directions D1 and D2. That is to say, in the first example, the first, second, and third directions D1, D2, and D3 intersect with each other at right angles.

The heat dissipation device 1 includes a base 2, a fin array 3, and an air flow channel 4. The heat dissipation device 1 is suitably made of a metallic material such as aluminum, iron, or copper.

The base 2 has a flat plate shape. When viewed in the first direction D1, the base 2 has a square or rectangular shape.

The fin array 3 includes a plurality of fins 5 and a reinforcing structure 6. The fin array 3 also includes second fins 52.

The plurality of fins 5 protrude in the first direction D1 from the base 2. The plurality of fins 5 are arranged side by side in the second direction D2. In the first example, the fin array 3 includes three fins 5, which are arranged side by side in the second direction D2.

The reinforcing structure 6 couples two adjacent fins 5 out of the plurality of fins 5. In the first example, the reinforcing structure 6 includes reinforcing members 61. Each of the reinforcing members 61 is bridged between the two adjacent fins 5 so as to be displaced in the first direction D1 and extend diagonally with respect to the second direction D2. More specifically, in the first example, the reinforcing structure 6 includes a reinforcing member 61, which couples one end, located closer to the base 2, of one of the two adjacent fins 5 to a point, located at a certain distance S7 away in the first direction D1 from the end located closer to the base 2, of the other fin 5. The reinforcing structure 6 also includes another reinforcing member 61, which couples a point, located at the certain distance S7 away in the first direction D1 from one end located closer to the base 2, of one of the two adjacent fins 5 to the end, located closer to the base 2, of the other fin 5. These two reinforcing members 61 cross each other and are integrated together. Thus, when viewed in the third direction D3, each pair of the two reinforcing members 61 has an X-shape.

In the first example, the reinforcing structure 6 further includes second reinforcing members 62, each of which is coupled to two adjacent fins 5. A point where each fin 5 and an associated one of the second reinforcing members 62 are coupled together agrees with a point where the fin 5 and the other end, opposite from the end closer to the base 2, of an associated reinforcing member 61 are coupled together. Each of the second reinforcing members 62 has a folded shape with a top protruding in the first direction D1 when viewed in the third direction D3.

In the first example, in each pair of adjacent fins 5 out of the plurality of fins 5, the reinforcing members 61 and the second reinforcing member 62 are bridged between the two adjacent fins 5.

Each of the second fins 52 protrudes in the first direction D1 from the reinforcing structure 6. More specifically, in the first example, each second fin 52 protrudes in the first direction D1 from the top of its associated second reinforcing member 62. Thus, the second fin 52 is located between the two adjacent fins 5. The second fin 52 has a shorter dimension as measured in the first direction D1 than the fins 5. The respective ends in the first direction D1 of the plurality of fins 5 and the end in the first direction D1 of the second fin 52 are arranged side by side in the second direction D2.

In the first example, the reinforcing structure 6 further includes a third reinforcing member 63. The third reinforcing member 63 is coupled to the respective ends in the first direction D1 of the plurality of fins 5. Specifically, the third reinforcing member 63 is located at the end in the first direction D1 of the fin array 3. The end in the second direction D2 of the third reinforcing member 63 is coupled to the end in the first direction D1 of one fin 5, located at the far end in the second direction D2, out of the plurality of fins 5. The other end in the opposite of the second direction D2 of the third reinforcing member 63 is coupled to the end in the first direction D1 of another fin 5, located at the end in the opposite of the second direction D2, out of the plurality of fins 5. In addition, the third reinforcing member 63 is also coupled to respective ends in the first direction D1 of the other fins 5 between those two ends. Furthermore, the third reinforcing member 63 is further coupled to respective ends in the first direction D1 of the second fins 52 between those two ends.

In the first example, when viewed in the third direction D3 intersecting with the first direction D1 and the second direction D2, the fin array 3 keeps the same shape anywhere in the third direction D3 except a region with the air flow channel 4.

Specifically, in the first example, the fins 5, the second fins 52, the reinforcing members 61, the second reinforcing members 62, and the third reinforcing member 63 each have a plate shape. The thickness of each of the fins 5, the second fins 52, the reinforcing members 61, the second reinforcing members 62, and the third reinforcing member 63 is perpendicular to the third direction D3. A cross-sectional shape of each of the fins 5, the second fins 52, the reinforcing members 61, the second reinforcing members 62, and the third reinforcing member 63 remains the same when taken along any plane perpendicular to the third direction D3, except a region with the air flow channel 4. Thus, the fins 5, the second fins 52, the reinforcing members 61, the second reinforcing members 62, the third reinforcing member 63, and the fin array 3 including these members have a shape continuous in the third direction D3, and have the same shape anywhere in the third direction D3 when viewed in the third direction D3, except the region with the air flow channel 4.

In the first example, the air flow channel 4 is a cylindrical space located inside the fin array 3 and opening at the end in the first direction D1 of the fin array 3. Although the air flow channel 4 is cylindrical in the first example, the air flow channel 4 may also have any other shape (such as a prismatic shape). Also, even though the air flow channel 4 is configured as a single flow channel, the air flow channel 4 may include a plurality of flow channels as well.

In the first example, the end in the first direction D1 of the air flow channel 4 opens to the outside. Meanwhile, the other end in the opposite of the first direction D1 of the air flow channel 4 is located between the crossing of the second reinforcing members 61 and the base 2, and the air flow channel 4 overlaps with the crossing between the two reinforcing members 61.

Each of the fins 5, second fins 52, and reinforcing structure 6 that are included in the fin array 3 has a cutaway shape where the air flow channel 4 is provided. Specifically, out of the plurality of fins 5, all of the fins 5, but the two fins 5 located at the end in the second direction D2 and at the other end in the opposite of the second direction D2, respectively, have a cutaway shape, which is opened in the second direction D2, the opposite of the second direction D2, and the first direction D1, at the region with the air flow channel 4. The second fins 52 also have a cutaway shape, which is opened in the second direction D2, the opposite of the second direction D2, and the first direction D1, at the region with the air flow channel 4. The third reinforcing member 63 has a cutaway shape, such as a hole running through itself in the first direction D1, at the region with the air flow channel 4. The second reinforcing members 62 also have a cutaway shape, such as a hole running through themselves in the first direction D1, at the region with the air flow channel 4. The reinforcing members 61 have a cutaway shape at the region with the air flow channel 4, i.e., at the point where the two reinforcing members 61 cross each other.

Thus, in the first example, the air flow channel 4 is surrounded with the fins 5, the second fins 52, and the reinforcing structure 6. Each of the spaces partitioned in the fin array 3 by the fins 5, the reinforcing structure 6, and the second fins 52 either communicates with, or forms at least part of, the air flow channel 4. These spaces are opened in the first direction D1 through the air flow channel 4.

In the first example, the heat dissipation device 1 has air inlet ports 7, each of which is provided to let the air flow channel 4 communicate with the outside of the fin array 3 in a direction intersecting with the first direction D1. In the first example, the reinforcing structure 6 forms the air inlet ports 7. Specifically, in the first example, the air inlet ports 7 include a plurality of holes 71, which are spaces partitioned in the fin array 3 by the fins 5, the reinforcing structure 6, and the second fins 52. The plurality of holes 71 includes holes 71 opening at one end in the third direction D3 and holes 71 opening at the other end in the opposite of the third direction D3. In this manner, the air inlet ports 7 allow the air flow channel 4 to communicate with the outside of the fin array 3 in the third direction D3.

In the first example of the heat dissipation device 1 with such a configuration, the fin array 3 includes the reinforcing structure 6 that couples two adjacent fins 5 together, and therefore, may have a rigid structure. This increases the resonant frequency of the fin array 3. In particular, according to the first example, the reinforcing structure 6 includes reinforcing members 61 bridged between the two adjacent fins 5 so as to be displaced in the first direction D1 and extend diagonally with respect to the second direction D2. Thus, the reinforcing members 61 give the fin array 3 a hardly deformable structure. This effectively increases the resonant frequency of the fin array 3. Particularly, in the first example, the reinforcing structure 6 includes the reinforcing members 61, each of which is coupled to the end, located closer to the base 2, of an associated one of the fins 5, as described above. The reinforcing members 61 make the portion, located closer to the base 2, of the fins 5 hardly deformable, thus substantially shortening the dimension as measured from a fixed end through a free end of each fin 5. This increases the resonant frequency particularly effectively.

In addition, in the first example, the heat dissipation device 1 includes the air flow channel 4. Thus, although the fin array 3 includes the reinforcing structure 6, which is usually capable of obstructing the air flow, the air flow channel 4 still facilitates the air flow through the fin array 3. Furthermore, the heat dissipation device 1 has the air inlet ports 7 that let the air flow channel 4 communicate with the outside of the fin array 3 in a direction intersecting with the first direction D1. This tends to produce the flow of the air that flows through the air inlet ports 7 into the air flow channel 4 and is exhausted in the first direction D1, thus allowing the heat in the fin array 3 to be dissipated efficiently due to the stack effect. Consequently, the heat dissipation device 1 is able to exhibit good heat dissipation properties.

Besides, in the first example, the reinforcing structure 6 forms the air inlet ports 7. This allows the reinforcing structure 6 to have not only the capability of lowering the resonant frequency of the fin array 3 but also the capability of improving the heat dissipation properties of the heat dissipation device 1 as well.

Moreover, the fin array 3 further includes the second fins 52 protruding in the first direction D1 from the reinforcing structure 6, and therefore, the second fins 52 further improve the heat dissipation properties of the heat dissipation device 1. Also, the reinforcing structure 6 may have the capability of supporting the second fins 52. Furthermore, the second fins 52 have a shorter dimension as measured in the first direction D1 than the plurality of fins 5. Thus, even when the heat dissipation device 1 includes the second fins 52, the resonant frequency of the heat dissipation device 1 may still be kept high enough.

The dimensions of the heat dissipation device 1 are not particularly limited. Irrespective of the dimensions, as long as the fin array 3 includes the reinforcing structure 6, the fin array 3 may be able to withstand vibrations more easily than a fin array 3 with no reinforcing structures 6. The fin array 3 may have the following dimensions, for example. The dimension S1 as measured in the third direction D3 of the overall fin array 3 may fall within the range from 30 mm to 35 mm, and the dimension S2 as measured in the second direction D2 of the overall fin array 3 may also fall within the range from 30 mm to 35 mm. The dimension S3 as measured in the first direction D1 of the fins 5 may fall within the range from 50 mm to 60 mm. The dimension S6 as measured in the first direction D1 of the second fins 52 may fall within the range from 20 mm to 25 mm. The gap S4 between two adjacent fins out of the fins 5 may fall within the range from 12 mm to 17 mm. The gap S5 between each fin 5 and an adjacent one of the second fins 52 may fall within the range from 5.5 mm to 8 mm. The certain distance S7 to the point where each reinforcing member 61 is coupled may fall within the range from 18 mm to 25 mm. The dimension S8 as measured in the first direction D1 of the air flow channel 4 may fall within the range from 43.5 mm to 46.5 mm. The diameter S9 of the air flow channel 4 as viewed in the opposite of the first direction D1 may fall within the range from 17 mm to 22 mm. The heat dissipation device 1 with such dimensions may have a resonant frequency that is three or more times as high as in a situation where no reinforcing structure 6 or air flow channel 4 is provided, and may also have heat dissipation properties comparable to the situation where no reinforcing structure 6 or air flow channel 4 is provided, although it depends on various conditions.

Next, a method of manufacturing the heat dissipation device 1 according to the first example will be described briefly. In the first example, when viewed in the third direction D3, the fin array 3 has the same shape anywhere in the third direction D3 except at the region with the air flow channel 4, as described above. Thus, the heat dissipation device 1 may be manufactured by a method including extrusion.

Specifically, a structure having the same shape as the fin array 3, except that the structure has no cutaway portion corresponding to the air flow channel 4, may be obtained by extruding a metallic material in a direction corresponding to the third direction D3. This extrusion process allows not only the structure but also the base 2 to be formed at a time. That is to say, an intermediate product in which the structure and the base 2 are formed integrally may be obtained by extrusion process. Subsequently, the air flow channel 4 may be formed by partially cutting out the structure by drilling or any other machining. This allows the heat dissipation device 1 to be manufactured highly efficiently with relatively light workload.

### 1-2. Second Example

A second example of the heat dissipation device 1 will be described with reference to FIGS. 2A and 2B. The second example of the heat dissipation device 1 has the same structure as the first example of the heat dissipation device 1 except that the heat dissipation device 1 (specifically, the reinforcing structure 6) includes no third reinforcing members 63. The second example of the heat dissipation device 1 achieves the same advantages as those of the first example of the heat dissipation device 1 except the ones achieved by the third reinforcing member 63.

### 1-3. Third Example

A third example of the heat dissipation device 1 will be described with reference to FIGS. 3A and 3B. In FIGS. 3A and 3B, a first direction D1, a second direction D2, and a third direction D3 according to the third example are also shown. These directions are the same as their counterparts of the first example.

The heat dissipation device 1 includes a base 2, a fin array 3, and an air flow channel 4. The heat dissipation device 1 is suitably made of a metallic material such as aluminum, iron, or copper.

The base 2 is the same as the counterpart of the first example.

The fin array 3 includes a plurality of fins 5 and a reinforcing structure 6.

The plurality of fins 5 protrude in the first direction D1 from the base 2. The plurality of fins 5 are arranged side by side in the second direction D2. In the third example, the fin array 3 includes five fins 5, which are arranged side by side in the second direction D2.

The reinforcing structure 6 couples two adjacent fins 5 out of the plurality of fins 5. In the third example, the reinforcing structure 6 includes reinforcing plates 64. A pair of reinforcing plates 64 is bridged between two adjacent fins 5. The second reinforcing plates 64 face each other in the third direction D3.

More specifically, each of the reinforcing plates 64 has the shape of a flat plate, of which the thickness is aligned with the third direction D3. The dimension as measured in the first direction D1 of the reinforcing plates 64 is equal to the dimension as measured in the first direction D1 of the fins 5. Thus, the gap between each pair of fins 5 is closed with the reinforcing plates 64, and a space surrounded with the two fins 5 and the two reinforcing plates 64 is present between the two fins 5. In the third example, the reinforcing structure 6 includes multiple pairs of reinforcing plates 64. Between any pair of adjacent fins 5, out of the plurality of fins 5, two reinforcing plates 64 that form a pair are bridged. Each pair of reinforcing plates 64 is coupled to associated fins 5 between one end in the third direction D3 of the fins 5 and the other end in the opposite of the third direction D3 of the fins 5. Thus, each fin 5 partially protrudes outward in the third direction D3 from the associated reinforcing plate 64.

In the third example, the air flow channel 4 is located inside the fin array 3 and opens at the end in the first direction D1 of the fin array 3. Also, in the third example, the air flow channel 4 includes a plurality of flow channels 41. The plurality of flow channels 41 includes flow channels 41, each of which is surrounded with associated two fins 5 and associated two reinforcing plates 64. That is to say, between two adjacent fins 5, there is a space surrounded with the two fins 5 and the two reinforcing plates 64 as described above. The space is used as the flow channel 41. The plurality of flow channels 41 are arranged side by side in the second direction D2. Each pair of adjacent flow channels 41 are partitioned from each other by an associated one of the fins 5. Thus, in the third example, the air flow channel 4 is surrounded with the fins 5 and the reinforcing structure 6, and each of the spaces partitioned in the fin array 3 by the fins 5 and the reinforcing structure 6 forms part of the air flow channel 4 and is opened in the first direction D1.

In the third example, the heat dissipation device 1 has air inlet ports 7 that allow the air flow channel 4 to communicate with the outside of the fin array 3 in a direction intersecting with the first direction D1. In the third example, the air inlet ports 7 are cut through the reinforcing structure 6, and include a plurality of holes 71. Specifically, in the third example, a plurality of holes 71 arranged in the first direction D1 are cut through each of the plurality of reinforcing plates 64. Thus, the air inlet ports 7 include a plurality of holes 71, each directly communicating with an associated one of the flow channels 41. In addition, since the holes 71 are cut through each of two reinforcing plates 64 that form a pair, the air inlet ports 7 include holes 71 opening toward one end in the third direction D3 and holes 71 opening toward the other end in the opposite of the third direction D3. Thus, the air inlet ports 7 allow the air flow channel 4 to communicate with the outside of the fin array 3 in the third direction.

In the third example of the heat dissipation device 1 with such a configuration, the fin array 3 includes the reinforcing structure 6 that couples two adjacent fins 5 together, and therefore, may have a rigid structure. This increases the resonant frequency of the fin array 3. In particular, according to the third example, the reinforcing structure 6 includes reinforcing plates 64. Two reinforcing plates 64 that form a pair are bridged between each pair of adjacent fins 5 and face each other in the third direction D3. Thus, the reinforcing plates 64 give the fin array 3 a hardly deformable structure. This effectively increases the resonant frequency of the fin array 3.

In addition, in the third example, the heat dissipation device 1 includes the air flow channel 4. Thus, although the fin array 3 includes the reinforcing structure 6, which is usually capable of obstructing the air flow, the air flow channel 4 still facilitates the air flow through the fin array 3. Besides, since the air flow channel 4 includes a plurality of flow channels 41, the air flow through the fin array 3 may be accelerated effectively by those flow channels 41. Furthermore, the heat dissipation device 1 has the air inlet ports 7 that communicate with the air flow channel 4 and that open in a direction intersecting with the first direction D1. This tends to produce the flow of the air that flows through the air inlet ports 7 into the air flow channel 4 and is exhausted in the first direction D1, thus allowing the heat in the fin array 3 to be dissipated efficiently due to the stack effect. On top of that, the air inlet ports 7 include a plurality of holes 71 directly communicating with the plurality of flow channels 41. This allows the air outside of the fin array 3 to flow directly into the respective flow channels 41 through the holes 71. This promotes the dissipation of the heat through the air flow channel 4 due to the stack effect. Moreover, each fin 5 partially protrudes outward in the third direction D3 from an associated reinforcing plate 64, thus allowing the heat to be dissipated efficiently through the protruding portion. Consequently, the heat dissipation device 1 is able to exhibit good heat dissipation properties.

Besides, in the third example, the air inlet ports 7 are cut through the reinforcing structure 6. This allows the reinforcing structure 6 to have not only the capability of lowering the resonant frequency of the fin array 3 but also the capability of improving the heat dissipation properties of the heat dissipation device 1 as well.

The dimensions of the heat dissipation device 1 are not particularly limited. Irrespective of the dimensions, as long as the fin array 3 includes the reinforcing structure 6, the fin array 3 may be able to withstand vibrations more easily than a fin array 3 with no reinforcing structures 6. The fin array 3 may have the following dimensions, for example. The dimension S1 as measured in the third direction D3 of the overall fin array 3 may fall within the range from 30 mm to 35 mm, and the dimension S2 as measured in the second direction D2 of the overall fin array 3 may also fall within the range from 30 mm to 35 mm. The dimension S3 as measured in the first direction D1 of the fins 5 may fall within the range from 50 mm to 60 mm. The gap S4 between two adjacent ones of the fins 5 may fall within the range from 5.5 mm to 8 mm. The heat dissipation device 1 with such dimensions may have a resonant frequency that is ten or more times as high as in a situation where no reinforcing structure 6 is provided, and may also have heat dissipation properties at least comparable to the situation where no reinforcing structure 6 is provided, although it depends on various conditions.

In the third example, the plurality of holes 71 included in the air inlet ports 7 are cut uniformly through each reinforcing plate 64 from one end through the other end in the first direction D1. However, the number and the locations of these holes 71 of the reinforcing plate 64 are only examples and should not be construed as limiting. Nevertheless, the air inlet ports 7 suitably include at least holes 71 cut through the reinforcing plates 64 in the vicinity of the base 2. This accelerates the dissipation of heat through the air flow channel 4 particularly efficiently due to the stack effect.

### 1-4. Fourth and Fifth Examples

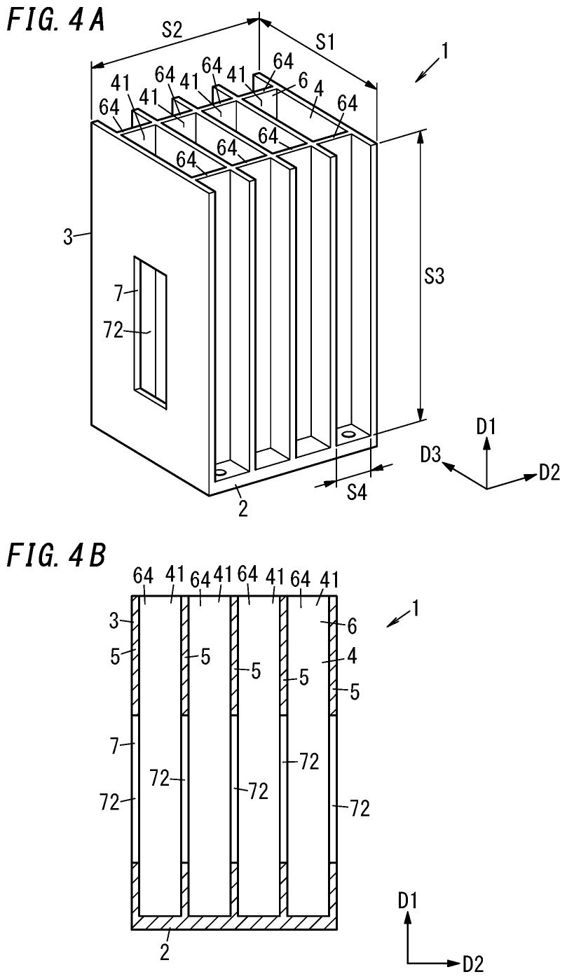

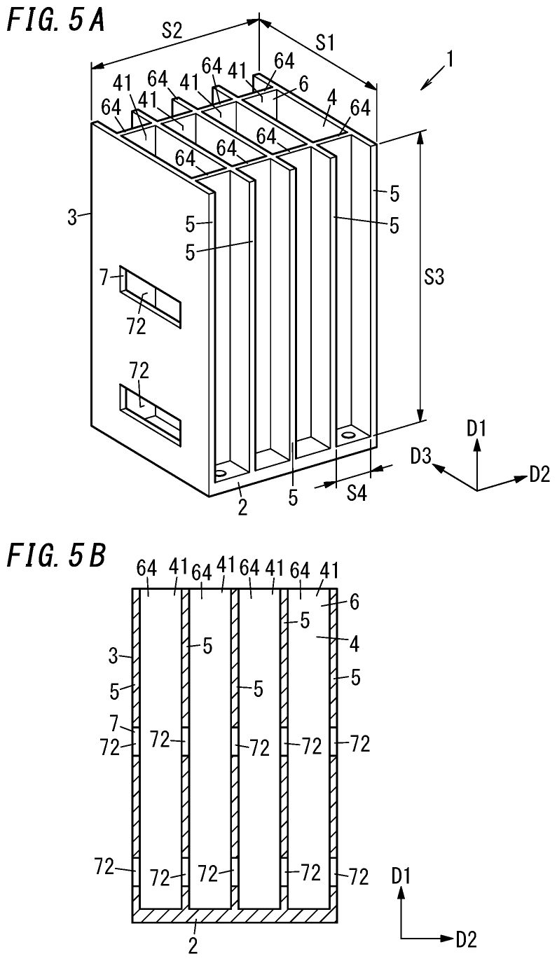

Next, fourth and fifth examples of the heat dissipation device 1 will be described with reference to FIGS. 4A and 4B and FIGS. 5A and 5B, respectively. In FIGS. 4A and 4B and FIGS. 5A and 5B, also shown are a first direction D1, a second direction D2, and a third direction D3 according to the fourth and fifth examples.

The fourth and fifth examples of the heat dissipation device 1 also have air inlet ports 7 allowing the air flow channel 4 to communicate with the outside of the fin array 3 in a direction intersecting with the first direction D1. The air inlet ports 7 are provided at different positions from the third example of the heat dissipation device 1. In the other respects, the fourth and fifth examples of the heat dissipation device 1 have the same structure as the third example of the heat dissipation device 1.

In the fourth and fifth examples of the heat dissipation device 1, the air inlet ports 7 include holes 72 cut through the plurality of fins 5. The hole 72 cut through the fin 5 located at the far end in the second direction D2 and the hole 72 cut through the fin 5 located at the other end in the opposite of the second direction D2 each allow the flow channel 41 adjacent to the fin 5 to communicate with the outside of the fin array 3. Meanwhile, the hole 72 cut through each of the other fins 5 allows the two flow channels 41, partitioned from each other by the fin 5, to communicate with each other. In this manner, the air inlet ports 7 allow the plurality of flow channels 41 to communicate in the second direction D2 with the outside of the fin array 3.

In the fourth example of the heat dissipation device 1, a single hole 72 is cut through each of the plurality of fins 5. This hole 72 has the shape of a rectangle elongated in the first direction D1.

In the fifth example of the heat dissipation device 1, two holes 72 are cut through each of the plurality of fins 5 so as to be arranged in the first direction D1. Each of these two holes 72 has the shape of a rectangle elongated in the third direction D3. One of these two holes 72 is located in the vicinity of the base 2.

The fourth and fifth examples of the heat dissipation device 1 with such a configuration increases the resonant frequency of the fin array 3 as effectively as the third example.

In addition, the fourth and fifth examples of the heat dissipation device 1 also exhibit as good heat dissipation properties as the third example.

The locations, shape, and number of the holes 72 of the fin array 3 according to the fourth and fifth examples are only examples and should not be construed as limiting. Nevertheless, as in the fifth example, the air inlet ports 7 suitably include at least holes 72 cut through the fins 5 in the vicinity of the base 2. This accelerates the dissipation of heat through the air flow channel 4 particularly efficiently due to the stack effect.

### 2. Reference Implementation

A heat dissipation device 1 according to a reference implementation related to the exemplary embodiment will now be described.

The heat dissipation device 1 according to the reference implementation has the same configuration as the heat dissipation device 1 according to the exemplary embodiment except that the reference implementation includes no air flow channels 4.

Specifically, a heat dissipation device 1 according to the reference implementation includes a base 2 and a fin array 3. The fin array 3 includes a plurality of fins 5. The plurality of fins 5 protrude in a first direction D1 from the base 2 and are arranged side by side in a second direction D2 that intersects with the first direction D1. The fin array 3 further includes a reinforcing structure 6 to couple two adjacent fins out of the plurality of fins 5.

When the heat dissipation device 1 according to the reference implementation is used, the base 2 of the heat dissipation device 1, for example, may be arranged on a heat source. Then, the heat generated from the heat source is conducted to the fin array 3 via the base 2 and then radiated from the fin array 3.

The heat dissipation device 1 according to the reference implementation allows the reinforcing structure 6 to increase the resonant frequency of the fin array 3 compared to a situation where no reinforcing structure 6 is provided. Thus, the reinforcing structure 6 is able to reduce the magnitude of displacement of the fin array 3 exposed to vibrations and thereby reduce the damage to be done to the fin array 3.

In the heat dissipation device 1 according to the reference implementation, the reinforcing structure 6 may include a reinforcing member 61 bridged between the two adjacent fins 5 so as to be displaced in the first direction D1 and extend diagonally with respect to the second direction D2. This allows the reinforcing member 61 to further increase the resonant frequency of the fin array 3.

In the heat dissipation device 1 according to the reference implementation, when viewed in the third direction D3 intersecting with the first direction D1 and the second direction D2, the fin array 3 may keep the same shape anywhere in the third direction D3. This allows the fin array 3 to be formed by extrusion.

In the heat dissipation device 1 according to the reference implementation, the air flow channel 4 may include a plurality of flow channels 41. This allows the flow channels 41 to improve the heat dissipation properties of the heat dissipation device 1.

In the heat dissipation device 1 according to the reference implementation, the fin array 3 may further include a second fin 52 protruding in the first direction D1 from the reinforcing structure 6 and having a shorter dimension as measured in the first direction D1 than the plurality of fins 5. This allows the reinforcing structure 6 to support the second fin 52 and also allows the second fin 52 to improve the heat dissipation properties of the heat dissipation device 1.

Now, first and second reference examples will be described as more specific examples of the heat dissipation device 1 according to the reference implementation. When the second reference example is described, any constituent element of the second reference example, having substantially the same function as a counterpart of the first reference example, will not be described all over again to avoid redundancies. Note that the following reference examples of the heat dissipation device 1 according to the reference implementation should not be construed as limiting, and that some constituent elements thereof may be readily replaced, omitted, or combined with additional elements as needed in various manners.

### 2-1. First Reference Example

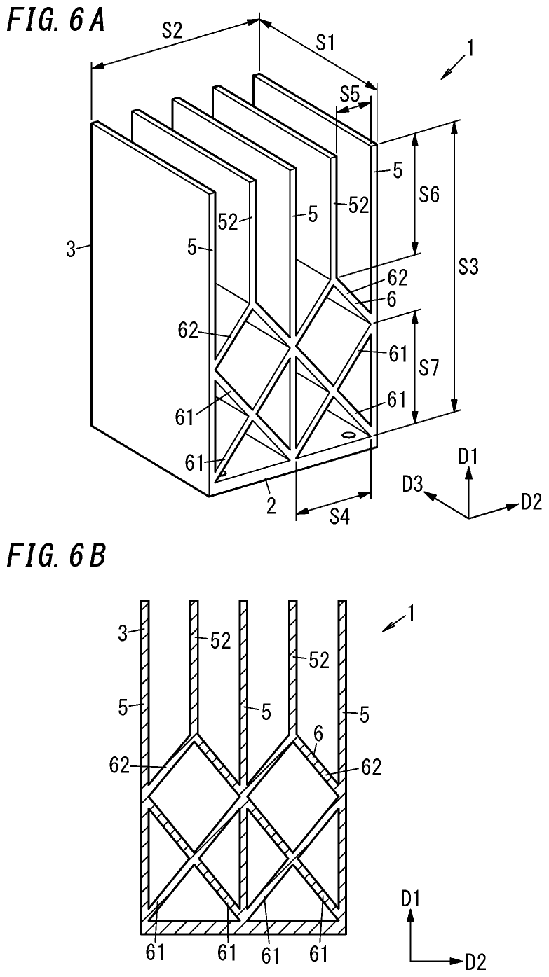

A first reference example of the heat dissipation device 1 will be described with reference to FIGS. 6A and 6B. In FIGS. 6A and 6B, the first, second, and third directions D1, D2, and D3 according to the first reference example are also shown. The second direction D2 intersects with the first direction D1, and the third direction D3 intersects with the first and second directions D1 and D2. As can be seen, these directions only need to intersect with each other. In the first reference example, the second direction D2 is perpendicular to the first direction D1, and the third direction D3 is perpendicular to the first and second directions D1 and D2. That is to say, in the first reference example, the first, second, and third directions D1, D2, and D3 intersect with each other at right angles.

The first reference example of the heat dissipation device 1 has no air flow channel 4. In the other respects, the first reference example of the heat dissipation device 1 has the same configuration as the second example of the heat dissipation device 1.

Specifically, the heat dissipation device 1 includes a base 2 and a fin array 3. The heat dissipation device 1 is suitably made of a metallic material such as aluminum, iron, or copper.

The base 2 has a flat plate shape. When viewed in the first direction D1, the base 2 has a square or rectangular shape.

The fin array 3 includes a plurality of fins 5 and a reinforcing structure 6. The fin array 3 also includes second fins 52.

The plurality of fins 5 protrude in the first direction D1 from the base 2. The plurality of fins 5 are arranged side by side in the second direction D2. In the first reference example, the fin array 3 includes three fins 5, which are arranged side by side in the second direction D2.

The reinforcing structure 6 couples two adjacent fins out of the plurality of fins 5. In the first reference example, the reinforcing structure 6 includes reinforcing members 61. Each of the reinforcing members 61 is bridged between the two adjacent fins 5 so as to be displaced in the first direction D1 and extend diagonally with respect to the second direction D2. More specifically, in the first reference example, the reinforcing structure 6 includes a reinforcing member 61, which couples one end, located closer to the base 2, of one of the two adjacent fins 5 to a point, located at a certain distance S7 away in the first direction D1 from the end located closer to the base 2, of the other fin 5. The reinforcing structure 6 also includes another reinforcing member 61, which couples a point, located at the certain distance S7 away in the first direction D1 from one end located closer to the base 2, of one of the two adjacent fins 5 to the end, located closer to the base 2, of the other fin 5. These two reinforcing members 61 cross each other and are integrated together. Thus, when viewed in the third direction D3, each pair of the two reinforcing members 61 has an X-shape.

In the first reference example, the reinforcing structure 6 further includes second reinforcing members 62, each of which is coupled to two adjacent fins 5. A point where each fin 5 and an associated one of the second reinforcing members 62 are coupled together agrees with a point where the fin 5 and the other end, opposite from the end closer to the base 2, of an associated reinforcing member 61 are coupled together. Each of the second reinforcing members 62 has a folded shape with a top protruding in the first direction D1 when viewed in the third direction D3.

In the first reference example, in each pair of adjacent fins 5 out of the plurality of fins 5, the reinforcing members 61 and the second reinforcing members 62 are bridged between the two adjacent fins 5.

Each of the second fins 52 protrudes in the first direction D1 from the reinforcing structure 6. More specifically, in the first reference example, each second fin 52 protrudes in the first direction D1 from the top of its associated second reinforcing member 62. The second fin 52 has a shorter dimension as measured in the first direction D1 than the fins 5. The respective ends in the first direction D1 of the plurality of fins 5 and the end in the first direction D1 of the second fin 52 are arranged side by side in the second direction D2.

In the first reference example, when viewed in the third direction D3 intersecting with the first direction D1 and the second direction D2, the fin array 3 keeps the same shape anywhere in the third direction D3.

Specifically, in the first reference example, the fins 5, the second fins 52, the reinforcing members 61, the second reinforcing members 62, and the third reinforcing member 63 each have a plate shape. The thickness of each of the fins 5, the second fins 52, the reinforcing members 61, the second reinforcing members 62, and the third reinforcing member 63 is perpendicular to the third direction D3. A cross-sectional shape of each of the fins 5, the second fins 52, the reinforcing members 61, the second reinforcing members 62, and the third reinforcing member 63 remains the same when taken along any plane perpendicular to the third direction D3. Thus, the fins 5, the second fins 52, the reinforcing members 61, the second reinforcing members 62, the third reinforcing member 63, and the fin array 3 including these members have a shape continuous in the third direction D3, and have the same shape anywhere in the third direction D3 when viewed in the third direction D3.

In the first reference example of the heat dissipation device 1 with such a configuration, the fin array 3 includes the reinforcing structure 6 that couples two adjacent fins 5 together, and therefore, may have a rigid structure. This increases the resonant frequency of the fin array 3. In particular, according to the first reference example, the reinforcing structure 6 includes reinforcing members 61, each bridged between the two adjacent fins 5 so as to be displaced in the first direction D1 and extend diagonally with respect to the second direction D2. Thus, the reinforcing members 61 give the fin array 3 a hardly deformable structure. This effectively increases the resonant frequency of the fin array 3. Particularly, in the first reference example, the reinforcing structure 6 includes the reinforcing members 61, each of which is coupled to the end, located closer to the base 2, of an associated one of the fins 5, as described above. The reinforcing members 61 make the portion, located closer to the base 2, of the fins 5 hardly deformable, thus substantially shortening the dimension as measured from a fixed end through a free end of each fin 5. This increases the resonant frequency particularly effectively.

Moreover, the fin array 3 further includes the second fins 52 protruding in the first direction D1 from the reinforcing structure 6, and the second fins 52 have a shorter dimension as measured in the first direction D1 than the plurality of fins 5. Therefore, the second fins 52 further improve the heat dissipation properties of the heat dissipation device 1. Also, the reinforcing structure 6 may have the capability of supporting the second fins 52. Furthermore, the second fins 52 have a shorter dimension than the plurality of fins 5. Thus, even when the heat dissipation device 1 includes the second fins 52, the resonant frequency of the heat dissipation device 1 may still be kept high enough.

The dimensions of the heat dissipation device 1 are not particularly limited. Irrespective of the dimensions, as long as the fin array 3 includes the reinforcing structure 6, the fin array 3 may be able to withstand vibrations more easily than a fin array 3 with no reinforcing structures 6. The fin array 3 may have the following dimensions, for example. The dimension S1 as measured in the third direction D3 of the overall fin array 3 may fall within the range from 30 mm to 35 mm, and the dimension S2 as measured in the second direction D2 of the overall fin array 3 may also fall within the range from 30 mm to 35 mm. The dimension S3 as measured in the first direction D1 of the fins 5 may fall within the range from 50 mm to 58 mm. The dimension S6 as measured in the first direction D1 of the second fins 52 may fall within the range from 20 mm to 25 mm. The gap S4 between two adjacent ones of the fins 5 may fall within the range from 12 mm to 17 mm. The gap S5 between each fin 5 and an adjacent one of the second fins 52 may fall within the range from 5.5 mm to 8 mm. The certain distance S7 to the point where each reinforcing member 61 is coupled may fall within the range from 18 mm to 25 mm. The heat dissipation device 1 with such dimensions may have a resonant frequency that is 4.5 or more times as high as in a situation where no reinforcing structure 6 is provided, and may also have heat dissipation properties comparable to the situation where no reinforcing structure 6 is provided, although it depends on various conditions.

Next, a method of manufacturing the heat dissipation device 1 according to the first reference example will be described briefly. In the first reference example, when viewed in the third direction D3, the fin array 3 has the same shape anywhere in the third direction D3, as described above. Thus, the heat dissipation device 1 may be manufactured by a method including extrusion.

Specifically, the fin array 3 may be obtained by extruding a metallic material in a direction corresponding to the third direction D3. This extrusion process allows not only the fin array 3 but also the base 2 to be formed at a time. That is to say, a heat dissipation device 1 in which the fin array 3 and the base 2 are formed integrally may be obtained by extrusion process. This allows the heat dissipation device 1 to be manufactured highly efficiently with relatively light workload.

### 2-2. Second Reference Example

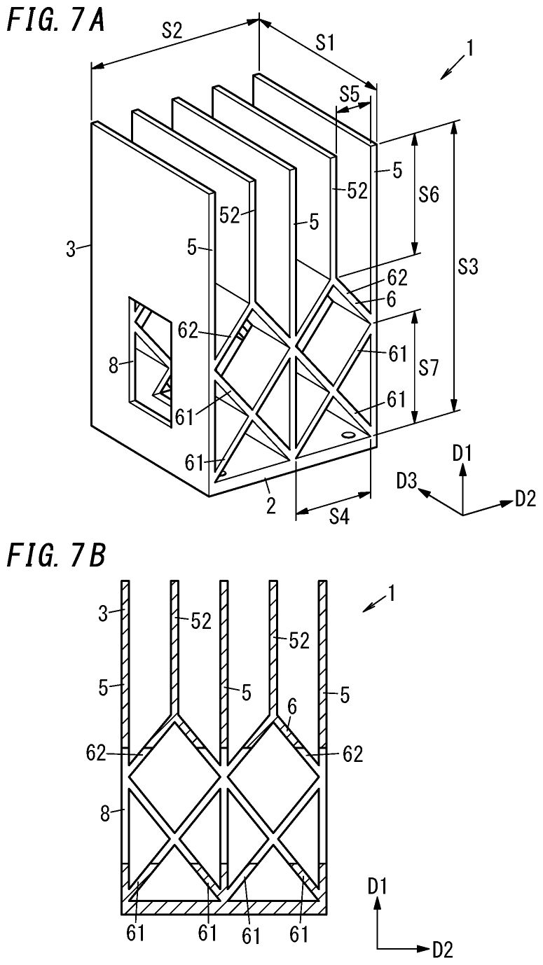

A second reference example of the heat dissipation device 1 will be described with reference to FIGS. 7A and 7B. The second reference example of the heat dissipation device 1 has the same structure as the first reference example of the heat dissipation device 1, except that the second reference example includes a through flow channel 8 running in the second direction D2 through the fin array 3.

Specifically, in this second reference example, the through flow channel 8 runs through the plurality of fins 5 and the reinforcing structure 6. One end in the first direction D1 of the through flow channel 8 is located closer to one end in the first direction D1 of the heat dissipation device 1 than the reinforcing members 61. The other end in the opposite of the first direction D1 of the air flow channel 4 is located closer to the other end in the opposite of the first direction D1 of the heat dissipation device 1 than the crossing between the two reinforcing members 61. Thus, each of the spaces partitioned in the fin array 3 by the constituent elements of the fin array 3, namely, the fins 5, the reinforcing structure 6, and the second fins 52, communicates with the through flow channel 8.

The second reference example of the heat dissipation device 1 achieves the same advantages as the first reference example of the heat dissipation device 1.

In addition, the second reference example of the heat dissipation device 1 further includes the through flow channel 8, and therefore, the air in the fin array 3 may be exchanged through the through flow channel 8 with the air outside of the fin array 3. Thus, the through flow channel 8 improves the heat dissipation properties of the heat dissipation device 1. In particular, according to the second reference example, each of the spaces partitioned in the fin array 3 by the constituent elements of the fin array 3 communicates with the through flow channel 8, and therefore, the through flow channel 8 further improves the heat dissipation properties of the heat dissipation device 1.

### 3. Power Generator

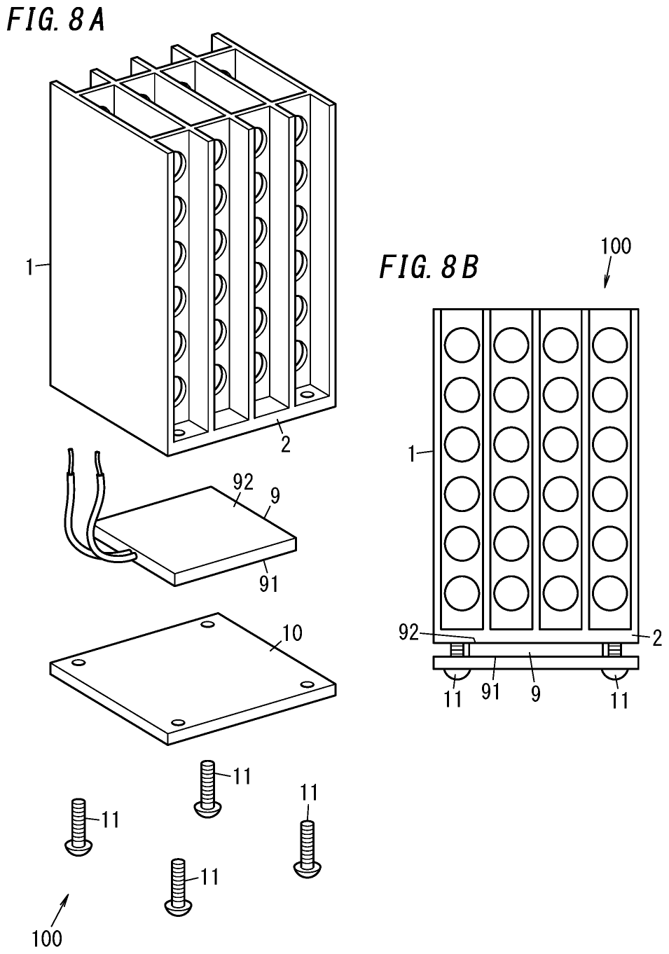

Next, a power generator 100 according to this embodiment will be described with reference to FIGS. 8A and 8B.

A power generator 100 according to this embodiment includes a thermoelectric power generation module 9 configured to convert thermal energy into electric energy; and the heat dissipation device 1 attached to the thermoelectric power generation module 9.

The power generator according to this embodiment achieves the advantages of allowing the heat dissipation device 1 to dissipate the heat generated from the thermoelectric power generation module 9, reducing the damage to be done to the heat dissipation device 1 exposed to vibrations, and allowing the heat dissipation device 1 to exhibit good heat dissipation properties.

Specifically, when heat is supplied to the thermoelectric power generation module 9, the heat dissipation device 1 is able to efficiently dissipate the heat from the thermoelectric power generation module 9, thus improving the power generation efficiency of the thermoelectric power generation module 9. In addition, even when the power generator 100 is exposed to vibrations, damage is hardly done to the heat dissipation device 1. Thus, even when used in an environment exposed to vibrations, the power generator 100 is still able to maintain good power generation efficiency for a long term.

A more specific example of the power generator 100 will be described. Note that the following specific example of the power generator 100 according to this embodiment is only an example and should not be construed as limiting and that some constituent elements thereof may be readily replaced, omitted, or combined with additional elements as needed in various manners.

The power generator 100 includes the thermoelectric power generation module 9 and the heat dissipation device 1 as described above. In this example, the power generator 100 further includes a thermoelectric plate 10.

The thermoelectric power generation module 9 is configured to, when the temperature of one surface 91 (hereinafter referred to as a “high-temperature surface 91”) thereof is higher than that of the other surface 92 (hereinafter referred to as a “low-temperature surface 92”) thereof, convert thermal energy into electric energy. The structure of the thermoelectric power generation module 9 is well known in the art, and the thermoelectric power generation module 9 may be implemented as a thermoelectric transducer such as a Peltier element.

The heat dissipation device 1 is attached to the thermoelectric power generation module 9 such that the base 2 of the heat dissipation device 1 is in contact with the low-temperature surface 92 of the thermoelectric power generation module 9. The heat dissipation device 1 of this example is supposed to be the third example of the heat dissipation device 1. However, this is only an example and should not be construed as limiting. Alternatively, the heat dissipation device 1 may also be any of the first, second, fourth, or fifth example described above. Still alternatively, the heat dissipation device 1 may also be the first reference example of the heat dissipation device 1.

The thermoelectric plate 10 may be a metallic plate, for example. The thermoelectric plate 10 is attached to the thermoelectric power generation module 9 so as to be in contact with the high-temperature surface 91 of the thermoelectric power generation module 9. Thus, when heated, the thermoelectric plate 10 is able to conduct heat to the high-temperature surface 91 efficiently.

In this example, the thermoelectric plate 10 is secured with screws 11 to the base 2 with the thermoelectric power generation module 9 interposed between the base 2 and the thermoelectric plate 10. In this manner, the heat dissipation device 1 and the thermoelectric plate 10 are attached to the thermoelectric power generation module 9.

When heat is supplied, via the thermoelectric plate 10, to the high-temperature surface 91 of the thermoelectric power generation module 9 of this power generator 100, the thermoelectric power generation module 9 is able to generate electricity due to the temperature difference between the high-temperature surface 91 and the low-temperature surface 92. The heat dissipation device 1 according to this embodiment is able to dissipate heat from the low-temperature surface 92, thus increasing the temperature difference between the high-temperature surface 91 and the low-temperature surface 92. This allows the thermoelectric power generation module 9 to generate electricity efficiently.

In addition, the heat dissipation device 1 according to this embodiment is able to reduce the damage to be done to itself even when exposed to vibrations. Thus, even if the power generator 100 is used in an environment exposed to vibrations, the heat dissipation device 1 is able to exhibit good heat dissipation properties for a long term. This allows the power generator 100 to generate electricity highly efficiently for a long term, thus saving trouble to do maintenance of, or replace, the heat dissipation device 1.

Therefore, the power generator 100 is effectively applicable as a power supply for a sensor device for detecting the temperature, pressure, or any other condition of a device that generates heat and vibration such as an internal combustion engine (hereinafter referred to as a “heat source device”) and transmitting the result wirelessly. In that case, attaching the power generator 100 to the heat source device so as to supply the heat generated by the heat source device to the high-temperature surface 91 allows the power generator 100 to generate electricity demanded by the sensor device. Generally speaking, it is often not easy to supply power via a cable to a sensor device, which is attached to any of various positions on the heat source device, from a distant location. However, the power generator 100 attached to the heat source device is able to supply power to the sensor device easily. In addition, even if the vibrations produced by the heat source device are transmitted to the power generator 100, the damage to be done to the heat dissipation device 1 is still reducible, thus allowing the power generator 100 to supply power to the sensor device with good stability for a long term.

As can be seen from the foregoing description of embodiments, a heat dissipation device (1) according to a first aspect includes a base (2), a fin array (3), and an air flow channel (4). The fin array (3) includes: a plurality of fins (5) protruding in a first direction (D1) from the base (2) and arranged side by side in a second direction (D2) that intersects with the first direction (D1); and a reinforcing structure (6) coupling two adjacent fins (5) out of the plurality of fins (5). The air flow channel (4) is surrounded, in the fin array (3), with the plurality of fins (5) and the reinforcing structure (6), and opens toward an end in the first direction (D1).

The heat dissipation device (1) according to the first aspect achieves the advantage of reducing the damage to be done to itself when exposed to vibrations and exhibiting good heat dissipation properties.

In a heat dissipation device (1) according to a second aspect, which may be implemented in conjunction with the first aspect, the reinforcing structure (6) includes a reinforcing member (61) bridged between the two adjacent fins (5) so as to be displaced in the first direction (D1) and extend diagonally with respect to the second direction (D2).

The second aspect allows the reinforcing member (61) to increase the resonant frequency of the fin array (3), compared to a situation where no reinforcing members (61) are provided.

In a heat dissipation device according to a third aspect, which may be implemented in conjunction with the first or second aspect, the fin array (3) keeps, when viewed in a third direction (D3) intersecting with the first direction (D1) and the second direction (D2), the same shape anywhere in the third direction (D3) except a region with the air flow channel (4).

The third aspect allows the fin array (3) to be formed by extrusion.

In a heat dissipation device (1) according to a fourth aspect, which may be implemented in conjunction with any one of the first to third aspects, the reinforcing structure (6) includes two reinforcing plates (64) bridged between the two adjacent fins (5) and facing each other in a third direction (D3) that intersects with the first direction (D1) and the second direction (D2). The air flow channel (4) includes a flow channel (41) surrounded with the two fins (5) and the two reinforcing plates (64).

The fourth aspect allows the reinforcing plates (64) to increase the resonant frequency of the fin array (3), compared to a situation where no reinforcing plates (64) are provided, and also allows the flow channel (41) to improve the heat dissipation properties of the heat dissipation device (1).

In a heat dissipation device (1) according to a fifth aspect, which may be implemented in conjunction with any one of the first to fourth aspects, the air flow channel (4) includes a plurality of flow channels (41).

The fifth aspect allows the plurality of flow channels (41) to improve the heat dissipation properties of the heat dissipation device (1).

A heat dissipation device (1) according to a sixth aspect, which may be implemented in conjunction with any one of the first to fifth aspects, further includes an air inlet port (7) that allows the air flow channel (4) to communicate with outside of the fin array (3) in a direction intersecting with the first direction (D1).

The sixth aspect causes the air inlet port (7) to produce a stack effect in the air flow channel (4), thus further improving the heat dissipation properties of the heat dissipation device (1) compared to a situation where no air inlet ports (7) are provided.

In a heat dissipation device (1) according to a seventh aspect, which may be implemented in conjunction with the sixth aspect, the reinforcing structure (6) forms the air inlet port (7).

The seventh aspect allows the reinforcing structure (6) to have not only the capability of lowering the resonant frequency of the fin array (3) but also the capability of improving the heat dissipation properties of the heat dissipation device (1).

In a heat dissipation device (1) according to an eighth aspect, which may be implemented in conjunction with the sixth aspect, the air inlet port (7) is cut through the reinforcing structure (6).

The eighth aspect allows the reinforcing structure (6) to have not only the capability of lowering the resonant frequency of the fin array (3) but also the capability of improving the heat dissipation properties of the heat dissipation device (1).

In a heat dissipation device (1) according to a ninth aspect, which may be implemented in conjunction with any one of the first to eighth aspects, the fin array (3) further includes a second fin (52) protruding in the first direction (D1) from the reinforcing structure (6) and having a shorter dimension as measured in the first direction (D1) than the plurality of fins (5).

The ninth aspect allows the reinforcing structure (6) to support the second fin (52) and also allows the second fin (52) to improve the heat dissipation properties of the heat dissipation device (1), compared to a situation where no second fins (52) are provided.

A power generator (100) according to a tenth aspect includes: a thermoelectric power generation module (9) configured to convert thermal energy into electric energy; and the heat dissipation device (1) according to any one of the first to ninth aspects attached to the thermoelectric power generation module (9).

The tenth aspect achieves the advantages of allowing the heat dissipation device (1) to dissipate the heat generated from the thermoelectric power generation module (9), reducing the damage to be done to the heat dissipation device (1) exposed to vibrations, and allowing the heat dissipation device (1) to exhibit good heat dissipation properties.

### REFERENCE SIGNS LIST

1 Heat Dissipation Device
2 Base
3 Fin Array
4 Air Flow Channel
41 Flow Channel
5 Fin
52 Second Fin
6 Reinforcing Structure
61 Reinforcing Member
64 Reinforcing Plate
7 Air Inlet Port
71 Hole
9 Thermoelectric Power Generation Module
100 Power Generator

1. A heat dissipation device comprising:
a base;
a fin array; and
an air flow channel,
the fin array including: a plurality of fins protruding in a first direction from the base and arranged side by side in a second direction that intersects with the first direction; and a reinforcing structure coupling two adjacent fins out of the plurality of fins,
the air flow channel being surrounded, in the fin array, with the plurality of fins and the reinforcing structure and opening toward an end in the first direction, and
the reinforcing structure including a reinforcing member bridged between the two adjacent fins so as to be displaced in the first direction and extend diagonally with respect to the second direction.

2. (canceled)

3. The heat dissipation device of claim 1, wherein
the fin array keeps, when viewed in a third direction intersecting with the first direction and the second direction, the same shape anywhere in the third direction, except a region with the air flow channel.

4. The heat dissipation device of claim 1, wherein
the reinforcing structure includes two reinforcing plates bridged between the two adjacent fins and facing each other in a third direction that intersects with the first direction and the second direction, and
the air flow channel includes a flow channel surrounded with the two fins and the two reinforcing plates.

5. The heat dissipation device of claim 1, wherein
the air flow channel includes a plurality of flow channels.

6. The heat dissipation device of claim 1, further comprising an air inlet port that allows the air flow channel to communicate with outside of the fin array in a direction intersecting with the first direction.

7. The heat dissipation device of claim 6, wherein
the reinforcing structure forms the air inlet port.

8. The heat dissipation device of claim 6, wherein
the air inlet port is cut through the reinforcing structure.

9. The heat dissipation device of claim 1, wherein
the fin array further includes a second fin protruding in the first direction from the reinforcing structure and having a shorter dimension as measured in the first direction than the plurality of fins.

10. A power generator comprising:
a thermoelectric power generation module configured to convert thermal energy into electric energy; and
the heat dissipation device of claim 1 attached to the thermoelectric power generation module.
